(19) United States
(12) Patent Application Publication
(10) Pub. No.: US 2010/0139758 A1
(43) Pub. Date: Jun. 10, 2010

(54) PHOTOVOLTAIC CELL STRUCTURE AND MANUFACTURING METHOD THEREOF

(75) Inventors: FENG FAN CHANG, KAOHSIUNG CITY (TW); HSIN CHIH LIN, TAICHUNG CITY (TW); HSIN HUNG LIN, YILAN COUNTY (TW); CHI HAU HSIEH, KAOHSIUNG CITY (TW); TZUNG ZONE LI, YUNLIN COUNTY (TW)

Correspondence Address: WPAT, PC;INTELLECTUAL PROPERTY ATTORNEYS, 2030 MAIN STREET, SUITE 1300, IRVINE, CA, 92614, US

(73) Assignee: RITDISPLAY CORPORATION, HSINCHU (TW)

(21) Appl. No.: 12/395,560

(22) Filed: Feb. 27, 2009

(30) Foreign Application Priority Data
Dec. 8, 2008 (TW) 097147584

(51) Int. Cl. H01L 31/0304; H01L 31/18

(52) U.S. Cl. 136/256; 438/46; 257/E21.09; 257/E31.019

(57) ABSTRACT

A photovoltaic cell structure includes a substrate, a metal layer, a p-type semiconductor layer, an n-type semiconductor layer and a transparent conductive layer. The substrate has a rough surface. The metal layer may include molybdenum and be formed on the rough surface. The p-type semiconductor layer is formed on the metal layer and may include CIGSS, CIGS, CIS, or compound of two or more of copper, selenium, sulfur. The n-type semiconductor layer is formed on the p-type semiconductor layer thereby forming a rough p-n junction surface. The n-type semiconductor layer may include CdS. The transparent conductive layer is formed on the n-type semiconductor layer. In an embodiment, the roughness Ra of the rough surface is between 0.01 to 100 μm.

### BACKGROUND OF THE INVENTION

(A) Field of the Invention

The present invention relates to a photovoltaic cell structure and manufacturing method thereof, and more specifically, to a thin-film photovoltaic cell structure including Copper Indium Gallium Selenium (CIGS) or Copper Indium Selenium (CIS).

(B) Description of the Related Art

Normally, copper Indium Gallium Diselenide thin-film solar cells are one of two types; one is comprised of copper, indium and selenium, and another is comprised of copper, indium, gallium and selenium. Because of the high photoelectrical efficiency and low material cost, solar cell development is expected to continue at a rapid pace. The photoelectrical efficiency of CIGS solar cells in the laboratory can reach around 19%, and 13% for related solar cell modules.

FIG. 1 shows a traditional CIGS photovoltaic cell structure 10, which is a laminate structure. The photovoltaic cell structure 10 includes a substrate 11, a metal layer 12, a CIGS layer 13, a buffer layer 14 and a transparent conductive layer (TCO) 15. The substrate 11 may be a glass substrate, and the metal layer 12 may be a molybdenum metal layer to comply with the chemical characteristics of CIGS and withstand high temperature while the CIGS layer 13 is deposited. The CIGS layer 13 is a p-type semiconductor layer. The buffer layer 14, which is an n-type semiconductor layer that may be made of cadmium sulfate (CdS), and the CIGS layer 13 form a p-n junction therebetween. The transparent conductive layer 15 may be zinc oxide (ZnO) with doped aluminum (AZO) or the like. The transparent conductive layer 15 is also called a window layer, and allows light to penetrate through it and reach the CIGS layer 13 beneath it.

U.S. Pat. No. 6,258,620 disclosed a CIGS photovoltaic cell structure like that shown in FIG. 1, in which the transparent conductive layer 15 is AZO, and an intrinsic ZnO layer is formed between the transparent conductive layer 15 and the buffer layer 14. Because voids may occur in the crystal growth of CIGS, shorts can easily occur between the transparent conductive layer 15 serving as a cathode and the metal layer 12 serving as an anode of the cell. The intrinsic ZnO layer is of high resistivity to avoid short occurrence. With such high resistivity, however, the efficiency of the photovoltaic cell is decreased. Therefore, there is a need to overcome these limitations.

### SUMMARY OF THE INVENTION

The present invention provides a photovoltaic cell structure and manufacturing method thereof, in which a rough substrate is used for effectively increasing the area of the p-n junction of the n-type semiconductor layer and the p-type semiconductor layer of the photovoltaic cell structure, thereby increasing the photocurrent density.

According to an embodiment of the present invention, a photovoltaic cell structure includes a substrate, a metal layer, a p-type semiconductor layer, an n-type semiconductor layer and a transparent conductive layer. The substrate has a rough surface; the metal layer may be a molybdenum layer formed on the rough surface of the substrate. The p-type semiconductor layer is formed on the metal layer and includes copper indium gallium selenium sulfur (CIGSS), copper indium gallium selenium (CIGS), copper indium sulfur (CIS), copper indium selenium (CIS) or includes a compound of at least two of copper, selenium or sulfur. The n-type semiconductor layer is formed on the p-type semiconductor layer, and a rough p-n junction is formed therebetween. In an embodiment, the n-type semiconductor layer may be cadmium sulfate (CdS). The transparent conductive layer is formed on the n-type semiconductor layer. In an embodiment, the rough surface has a roughness between 0.01 and 100 μm.

The manufacturing method of the above photovoltaic cell structure may include the steps of providing a substrate; roughing the substrate to form a rough surface on the substrate; forming a metal layer on the rough surface; forming a p-type semiconductor layer on the metal layer, the p-type semiconductor layer comprising copper indium gallium selenium sulfur, copper indium gallium selenium, copper indium sulfur, copper indium selenium or a compound of at least two of copper, selenium or sulfur; forming an n-type semiconductor layer on the p-type semiconductor layer, thereby forming a rough p-n junction between the n-type semiconductor layer and the p-type semiconductor layer; and forming a transparent conductive layer on the n-type semiconductor layer.

In an embodiment, the substrate is glass substrate and may be roughed by etching or sand blasting, or preferably by sand blasting followed by etching. In another embodiment, the rough surface can be formed by depositing metal films on the substrate and etching the metal films If the substrate is a metal substrate, the rough surface can be formed by etching or mechanical embossing.

### BRIEF DESCRIPTION OF THE DRAWINGS

FIG. 1 shows a known photovoltaic cell structure;

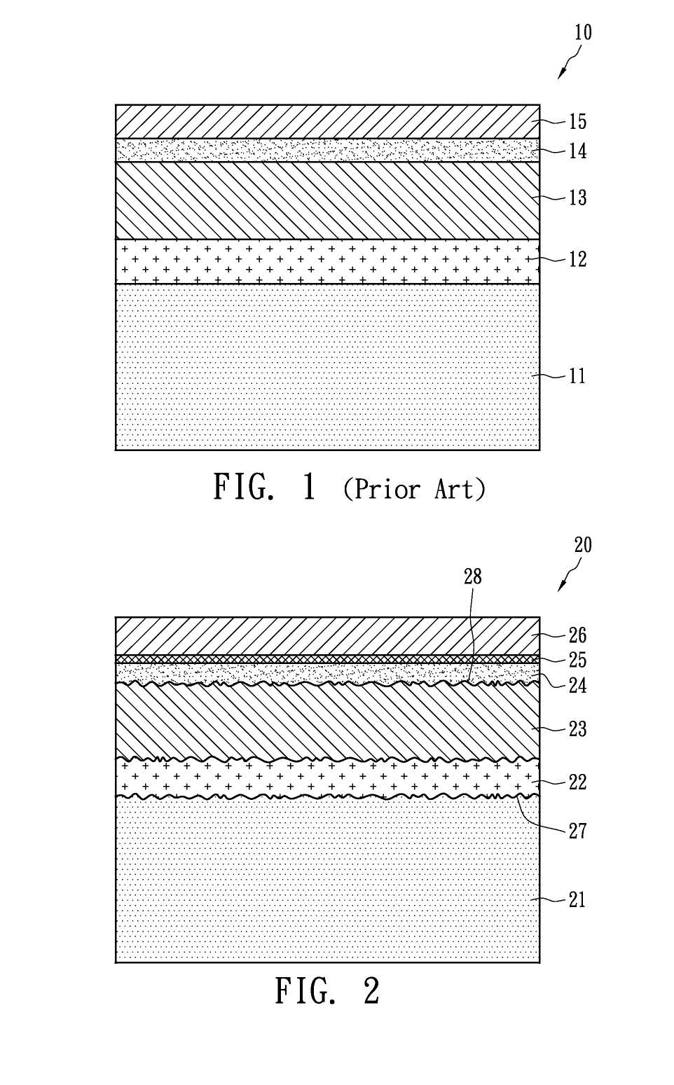

FIG. 2 shows a photovoltaic cell structure in accordance with an embodiment of the present invention;

FIG. 3 shows a manufacturing method of the photovoltaic cell structure in accordance with an embodiment of the present invention; and

FIG. 4 and FIG. 5 show substrate roughing embodiments for the photovoltaic cell structure of the present invention.

### DETAILED DESCRIPTION OF THE INVENTION

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

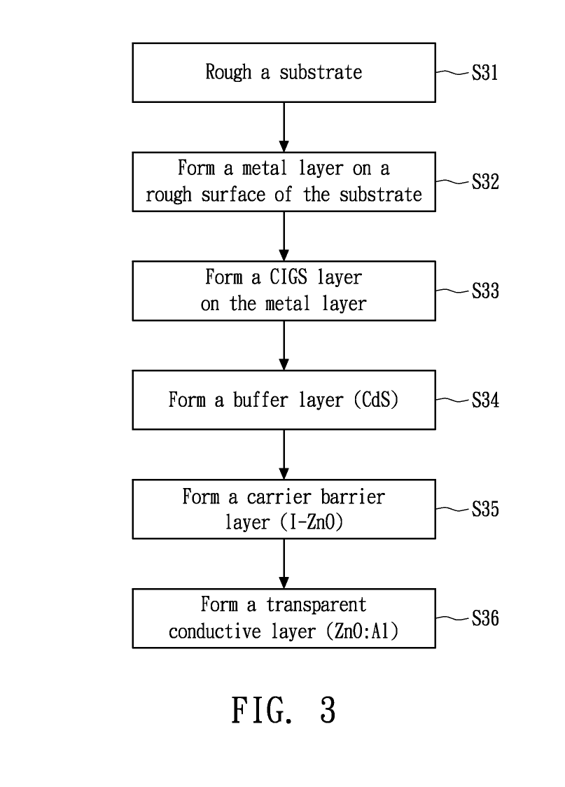

FIG. 2 shows a photovoltaic cell structure in accordance with an embodiment of the present invention. A photovoltaic cell structure 20 is a laminated structure and includes a substrate 21, a metal layer 22, a p-type semiconductor layer 23, an n-type semiconductor layer 24, a carrier barrier layer 25 and a transparent conductive layer 26. In addition to a glass substrate, the substrate 21 may be a polyimide flexible substrate, or a metal plate or a metal foil of stainless steel, molybdenum, copper, titanium or aluminum and has a rough surface 27. The substrate 21 is used for film formation and the shape thereof is not restricted to a plate; others such as a ball or specific or arbitrary shapes also can be used. In an embodiment, the roughness Ra of the substrate 21 is between 0.01 μm and 100 μm. The metal layer 22 may be a molybdenum layer of a thickness between 0.5 and 1 μm and be formed on the surface 27 of the substrate 21 to be a back contact metal layer of the cell. The p-type semiconductor layer 23 is formed on the metal layer 22 and may include a compound of copper indium gallium selenium sulfur (CIGSS), copper indium gallium selenium (CIGS), copper indium sulfur (CIS), copper indium selenium (CIS) or a compound of at least two of copper, selenium or sulfur. The thickness of the p-type semiconductor layer 23 may be between 2 and 3 micrometers. The n-type semiconductor layer 24 is formed on the p-type semiconductor layer 23, thereby forming a rough p-n junction 28 therebetween. In an embodiment, the n-type semiconductor layer 24 may be cadmium sulfate (CdS), zinc sulfate (ZnS) or indium sulfate (InS), and is much thinner than the p-type semiconductor layer 24, e.g., 50 nm, and has to be transparent, allowing sunlight to penetrate through it. The carrier barrier layer 25 is formed on the surface of the n-type semiconductor layer 24 and may be an intrinsic ZnO layer to avoid shorts between the metal layer 22 and the transparent conductive layer 26. The transparent conductive layer 26 is formed on the surface of the carrier barrier layer 25, and may be indium tin oxide (ITO), indium zinc oxide (IZO), aluminum zinc oxide (AZO), gallium zinc oxide (GZO), aluminum gallium zinc oxide (GAZO), cadmium tin oxide (CTO), zinc oxide (ZnO) and zirconium dioxide (ZrO₂) or other transparent conductive materials.

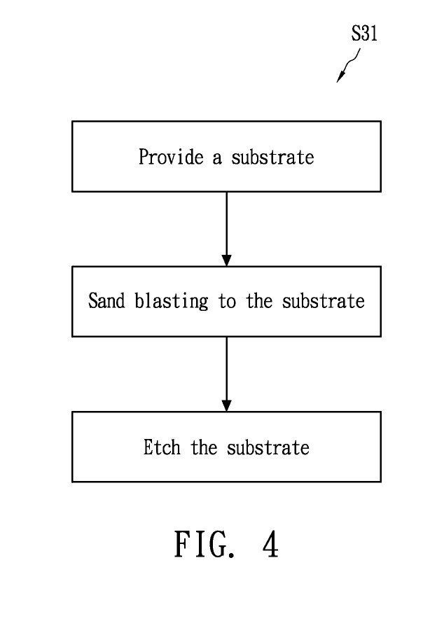

FIG. 3 shows the flow chart of the manufacturing method of the photovoltaic cell structure in accordance with the present invention. In step S31, the substrate 21 is roughed. In an embodiment, the roughness Ra of the surface of the substrate 21 is between 0.01 μm and 100 μm. If the roughness is not high enough, the increase of the area of the p-n junction 28 is not significant and therefore the increase of light absorption is limited. In contrast, if the surface is too rough, the subsequent metal layer 22 is not easily formed thereon.

In step S32, the metal layer 22 is formed by sputtering. In an embodiment, a molybdenum layer is used to comply with the chemical characteristics of CIS or CIGS and withstand high temperature while the p-type semiconductor layer 23, e.g., a CIGS layer, is deposited.

In step S33, the p-type semiconductor layer 23 is formed. In this embodiment, a CIGS layer is deposited on the metal layer 22. The CIGS deposition can formed by co-evaporation from elemental sources, selenization of metallic precursor layer, evaporation from compound source, chemical vapor deposition, close-spaced vapor transport, spray pyrolysis, electrodeposition, low temperature liquid phase method for precursor deposition, or chalcogenization of particulate precursor layer.

In step S34, the n-type semiconductor layer 24, e.g., a buffer layer, is formed. In an embodiment, a cadmium sulfate (CdS) layer of approximately 50 nm is formed. The CdS layer can prevent the CIGS layer from being damaged while the ZnO layer is formed by sputtering subsequently.

When the substrate 21 is roughed, the subsequent formation of the p-type semiconductor layer 23 and n-type semiconductor layer 24 conforms to the contour of the rough surface to form rough junctions, thereby increasing the area of the p-n junction 28 between the p-type semiconductor layer 23 and the n-type semiconductor layer 24.

In step S35, the carrier barrier layer 25 is formed. In an embodiment, the carrier barrier layer 25 can be intrinsic ZnO (I—ZnO) layer that can be formed by radio frequency (RF) sputtering.

In step S36, the transparent conductive layer 36 is formed on the carrier barrier layer 35. In an embodiment, the transparent conductive layer 36 includes a doped zinc oxide of a thickness of 0.35 to 0.5 μm that is formed by RF sputtering, in which aluminum is used as donor. This layer can be named ZnO:Al.

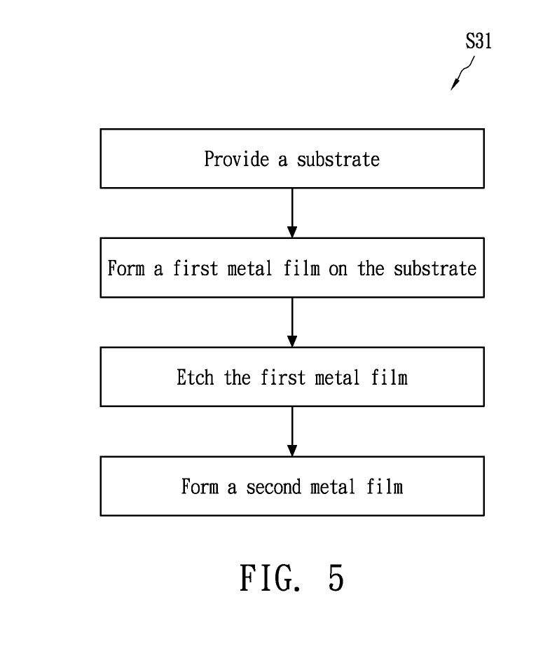

Because the photovoltaic cell structure of the present invention uses top illumination, the substrate 21 can be either transparent or opaque. If the substrate 21 is a transparent glass substrate, it can be roughed by etching, sand blasting or sand blasting followed by etching. In an embodiment, etching for roughness is performed by BaSO₄+(NH₄)HF₂+H₂O. The way of sand blasting followed by etching may use hydrofluoric acid (HF) as etching solution to remove glass debris after sand blasting; the process flow is shown in FIG. 4. If the surface 27 becomes too rough after sand blasting, the substrate 21 can be polished first before etching. Generally, the surface formed by etching is more flat compared to that formed by sand blasting. The method of sand blasting followed by etching can combine the advantages of sand blasting and etching.

Moreover, a first metal film can be formed on the substrate 21 first and be etched by dry etching or wet etching to form a rough surface, and subsequently forming a second metal film to form the roughed substrate 21; the process flow is shown in FIG. 5.

In addition, if the substrate 21 is made of metal, mechanical embossing can be used to form the rough substrate 21.

The following table shows the electrical experiment results of the photovoltaic cell with a rough substrate and without a rough substrate, in which Jsc is short current density, Voc is an open voltage, Jmax is current density of maximum power, Vmax is a voltage of maximum power.

| | | | | | Fill | |
|---|---|---|---|---|---|---|
| | Jsc | Voc | Jmax | Vmax | Factor | Efficiency |
| Substrate | (mA/cm²) | (V) | (mA/cm²) | (V) | (a.u.) | (%) |
| Non-rough | 29.94 | 0.52 | 26.25 | 0.42 | 0.72 | 10.90 |
| substrate | | | | | | |
| Rough | 36.54 | 0.55 | 30.33 | 0.43 | 0.65 | 13.10 |
| substrate | | | | | | |

In view of the above table, the photovoltaic cell structure of a rough substrate has higher efficiency of power generation. In other words, the present invention uses the rough substrate to effectively increase the surface of the p-n junction of the p-type semiconductor layer and the n-type semiconductor layer of the photovoltaic cell, thereby increasing photocurrent density and power generation efficiency.

The above-described embodiments of the present invention are intended to be illustrative only. Numerous alternative embodiments may be devised by those skilled in the art without departing from the scope of the following claims.

What is claimed is:

1. A photovoltaic cell structure, comprising:
a substrate having a rough surface;
a metal layer formed on the rough surface of the substrate;
a p-type semiconductor layer formed on the metal layer and comprising copper indium gallium selenium sulfur, copper indium gallium selenium, copper indium sulfur, copper indium selenium or comprising a compound of at least two of copper, selenium or sulfur;
an n-type semiconductor layer formed on the p-type semiconductor layer, thereby forming a rough p-n junction therebetween; and
a transparent conductive layer formed on the n-type semiconductor layer.

2. The photovoltaic cell structure of claim 1, wherein the rough surface has a roughness between 0.01 and 100 μm.

3. The photovoltaic cell structure of claim 1, wherein the rough p-n junction has a roughness between 0.01 and 100 μm.

4. The photovoltaic cell structure of claim 1, wherein the substrate is a glass substrate, a polyimide flexible board, a metal plate or a metal foil of stainless steel, molybdenum, copper, titanium or aluminum.

5. The photovoltaic cell structure of claim 4, wherein the rough surface is formed by sand blasting or etching.

6. The photovoltaic cell structure of claim 4, wherein the rough surface is formed by sand blasting followed by etching.

7. The photovoltaic cell structure of claim 1, wherein the substrate is a metal substrate.

8. The photovoltaic cell structure of claim 7, wherein the rough surface is formed by etching or mechanical embossing.

9. The photovoltaic cell structure of claim 1, wherein the metal layer comprises molybdenum.

10. The photovoltaic cell structure of claim 1, wherein the n-type semiconductor layer comprises cadmium sulfate, zinc sulfate or indium sulfate.

11. The photovoltaic cell structure of claim 1, further comprising a carrier barrier layer between the n-type semiconductor layer and the transparent conductive layer.

12. The photovoltaic cell structure of claim 1, wherein the transparent conductive layer comprises indium tin oxide, indium zinc oxide, aluminum zinc oxide, gallium zinc oxide, aluminum gallium zinc oxide, cadmium tin oxide, zinc oxide or zirconium dioxide.

13. A manufacturing method of a photovoltaic cell structure, comprising the steps of:
providing a substrate;
roughing the substrate to form a rough surface on the substrate;
forming a metal layer on the rough surface;
forming a p-type semiconductor layer on the metal layer, the p-type semiconductor layer comprising copper indium gallium selenium sulfur, copper indium gallium selenium, copper indium sulfur, copper indium selenium or comprising a compound of at least two of copper, selenium or sulfur;
forming an n-type semiconductor layer on the p-type semiconductor layer, thereby forming a rough p-n junction between the n-type semiconductor layer and the p-type semiconductor layer; and
forming a transparent conductive layer on the n-type semiconductor layer.

14. The manufacturing method of a photovoltaic cell structure of claim 13, wherein the rough surface has a roughness between 0.01 and 100 μm.

15. The manufacturing method of a photovoltaic cell structure of claim 13, wherein the rough p-n junction has a roughness between 0.01 and 100 μm.

16. The manufacturing method of a photovoltaic cell structure of claim 13, wherein the substrate is a glass substrate, and the step of roughing the substrate comprises etching and sand blasting.

17. The manufacturing method of a photovoltaic cell structure of claim 16, wherein the step of roughing the substrate comprises sand blasting followed by etching.

18. The manufacturing method of a photovoltaic cell structure of claim 16, wherein the etching uses hydrofluoric acid.

19. The manufacturing method of a photovoltaic cell structure of claim 13, wherein the substrate is a metal substrate, and the step of roughing the substrate comprises etching or mechanical embossing.

20. The manufacturing method of a photovoltaic cell structure of claim 13, wherein roughing the substrate comprises:
forming a first metal film on the substrate;
roughing the first metal film by etching; and
forming a second metal film on the first metal film.

21. The manufacturing method of a photovoltaic cell structure of claim 13, wherein the metal layer is formed by sputtering.

22. The manufacturing method of a photovoltaic cell structure of claim 13, wherein the p-type semiconductor layer is formed by co-evaporation from elemental sources, selenization of metallic precursor layer, evaporation from compound source, chemical vapor deposition, close-spaced vapor transport, spray pyrolysis, electrodeposition, low temperature liquid phase method for precursor deposition, or chalcogenization of particulate precursor layer.

23. The manufacturing method of a photovoltaic cell structure of claim 13, further comprising a step of forming a carrier barrier layer before forming the transparent conductive layer on the n-type semiconductor layer; the carrier barrier layer being formed between the n-type semiconductor layer and the transparent conductive layer.
